(19) United States
(12) Patent Application Publication
(10) Pub. No.: US 2026/0136138 A1
(43) Pub. Date: May 14, 2026

(54) PIEZOELECTRIC MICROELECTROMECHANICAL DEVICE WITH EMBOSSED CANTILEVER REGIONS

(71) Applicant: QUALCOMM Incorporated, San Diego, CA (US)

(72) Inventors: Robert John LITTRELL, Belmont, MA (US); Hamid BASAERI, Medford, MA (US); Craig CORE, North Andover, MA (US)

(21) Appl. No.: 19/248,302

(22) Filed: Jun. 24, 2025

Related U.S. Application Data
(60) Provisional application No. 63/718,222, filed on Nov. 8, 2024.

(51) Int. Cl. H04R 17/02; H04R 31/00; H10N 30/057; H10N 30/50

(52) U.S. Cl. CPC H04R 17/02; H04R 31/006; H10N 30/057; H10N 30/50; H04R 2201/003

(57) ABSTRACT

Aspects of the disclosure relate to piezoelectric microelectromechanical systems (MEMS) devices. A piezoelectric MEMS device may include a transducer body including an acoustic cavity extending from a bottom surface to a top surface and a piezoelectric cantilever disposed over the top surface and comprising a sensing region and a lever region including an embossed structure. The embossed structure comprises a non-planar portion disposed in the lever region and the non-planar portion is offset by 1.5 microns with respect to edges of the lever region. In some aspects, the piezoelectric cantilever is part of a plurality of piezoelectric cantilevers disposed over the top surface of the transducer body.

### CROSS-REFERENCE TO RELATED APPLICATION

This application claims the benefit of U.S. Provisional Application No. 63/718,222, filed Nov. 8, 2024, which is hereby incorporated by reference, in its entirety and for all purposes.

### TECHNICAL FIELD

This disclosure relates generally to acoustic transducers, and more specifically to piezoelectric microelectromechanical systems (MEMS) devices with embossed regions.

### BACKGROUND

Micro-electro-mechanical system (MEMS) devices can be used in a variety of contexts. Piezoelectric MEMS devices, for example, can be used as transducers. A micro-electro-mechanical system (MEMS) acoustic transducer/sensor converts acoustic energy into electrical signal, and/or converts an electrical signal into acoustic energy. An example of a MEMS acoustic transducer is a MEMS microphone, which converts sound pressure into an electrical voltage. Based on their transduction mechanisms, MEMS microphones can be made in various forms, such as capacitive microphones or piezoelectric microphones.

MEMS capacitive microphones and electric condenser microphones (ECMs) currently dominate the consumer electronics market for microphones. Piezoelectric MEMS microphones, however, occupy a growing portion of the consumer market, and have unique advantages compared to their capacitive counterparts. Among other things, piezoelectric MEMS microphones do not require a back plate, eliminating the squeeze film damping, which is an intrinsic noise source for capacitive MEMS microphones. In addition, piezoelectric MEMS microphones are reflow-compatible and can be mounted to a printed circuit board (PCB) using typical lead-free solder processing, which could irreparably damage typical ECMs.

### SUMMARY

Aspects of the present disclosure describe devices, systems, and methods for fabrication of piezoelectric microelectromechanical system (MEMS) devices. According to at least one illustrative example, an apparatus is provided. The apparatus includes a transducer body including an acoustic cavity extending from a bottom surface to a top surface; and a piezoelectric cantilever disposed over the top surface and comprising a sensing region and a lever region including an embossed structure.

In some aspects, one or more of the apparatuses described above is, is part of, or includes a mobile device (e.g., a mobile telephone or so-called “smart phone” or other mobile device), a wearable device, an extended reality device (e.g., a virtual reality (VR) device, an augmented reality (AR) device, or a mixed reality (MR) device), a personal computer, a laptop computer, a server computer, a vehicle (e.g., a computing device of a vehicle), or other device. In some aspects, an apparatus includes a camera or multiple cameras for capturing one or more images. In some aspects, the apparatus includes a display for displaying one or more images, notifications, and/or other displayable data. In some aspects, the apparatus can include one or more sensors. In some cases, the one or more sensors can be used for determining a location and/or pose of the apparatus, a state of the apparatuses, and/or for other purposes.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and embodiments, will become more apparent upon referring to the following specification, claims, and accompanying drawings.

### BRIEF DESCRIPTION OF DRAWINGS

FIG. 1 illustrates a microelectromechanical systems (MEMS) transducer including an embossed structure in accordance with aspects described herein;

FIG. 2 is a perspective view of a piezoelectric cantilever and stress applied at different portions of the piezoelectric cantilever;

FIG. 3 illustrates aspects of a MEMS sensor in accordance with aspects described herein;

FIG. 4 illustrates aspects of a piezoelectric microelectromechanical system (MEMS) sensor in accordance with aspects described herein;

FIG. 5A illustrates a plan view of a MEMs piezoelectric transducer in accordance with some aspects of the disclosure;

FIG. 5B illustrates a cross-sectional view of a MEMs piezoelectric transducer in accordance with some aspects of the disclosure;

FIG. 5C illustrates a plan view of another MEMs piezoelectric transducer in accordance with some aspects of the disclosure;

FIG. 5D illustrates a cross-sectional view of a MEMs piezoelectric transducer in accordance with some aspects of the disclosure;

FIG. 6A illustrates a piezoelectric cantilever including an embossed structure 610 in accordance with some aspects of the disclosure;

FIG. 6B is a cross-section of the piezoelectric cantilever along line B-B′ in accordance with some aspects of the disclosure;

FIG. 6C is a plan view of the piezoelectric cantilever in accordance with some aspects of the disclosure;

FIG. 7A illustrates a piezoelectric cantilever having an embossed structure including a stress dispersing features in accordance with some aspects of the disclosure;

FIG. 7B illustrates a piezoelectric cantilever having an embossed structure including stress dispersing features in accordance with some aspects of the disclosure;

FIG. 7C illustrates a piezoelectric cantilever having an embossed structure configured on a single axis in accordance with some aspects of the disclosure;

FIG. 7D illustrates a piezoelectric cantilever having an embossed structure including stress dispersing features in accordance with some aspects of the disclosure;

FIG. 7E illustrates a piezoelectric cantilever 750 having an embossed border structure in accordance with some aspects of the disclosure;

FIG. 7F is a cross-section of the piezoelectric cantilever 750 along line D-D′ in accordance with some aspects of the disclosure;

FIG. 7G is another cross-section of the piezoelectric cantilever 750 along line D-D′ in accordance with some aspects of the disclosure;

FIGS. 8A-8C illustrate a process of generating a piezoelectric cantilever for a MEMS transducer in accordance with some aspects of the disclosure;

FIG. 9 illustrates a method for manufacturing piezoelectric devices in accordance with aspects described herein; and

FIG. 10 is a block diagram of a computing device that can include a MEMS device in accordance with aspects described herein.

Like reference symbols in the various drawings indicate like elements.

### DETAILED DESCRIPTION

The detailed description set forth below in connection with the appended drawings is intended as a description of example aspects and implementations and is not intended to represent the only implementations in which the invention may be practiced. The detailed description includes specific details for the purpose of providing a thorough understanding of the example aspects and implementations. In some instances, some devices are shown in block diagram form. Drawing elements that are common among the following figures may be identified using the same reference numerals.

Piezoelectric devices operate using the piezoelectric effect, where mechanical displacement in a piezoelectric material generates an electrical charge. The electrical charge can be converted into a voltage by adding electrodes. Piezoelectric devices can operate as transducers for converting electrical energy into sound waves or mechanical energy from acoustic waves into electrical energy.

Piezoelectric devices are manufactured using semiconductor processes and result in remarkably small products. Their compact size allows piezoelectric devices to be embedded in tiny sensors, wearable devices, and even medical implants without significantly impacting the design or weight of these devices and are used in devices that require energy harvesting or precise actuation in limited spaces.

Piezoelectric MEMS devices are designed to have some target capacitance and to maximize sensitivity or output signal for that given capacitance. Piezoelectric material that is deformed or stressed generates this output while material with little or no deformation or stress looks more like stray capacitance and reduces the output signal. Lower output signal strength directly affects both signal-to-noise ratio (SNR) and dynamic range, which are of particular importance to acoustic applications such as microphones.

Aspects described herein include microelectromechanical systems (MEMS) acoustic transducers with piezoelectric cantilevers including embossed structures (e.g., embossed regions). In some aspects, a piezoelectric cantilever generates a voltage based on an amount of stress applied to an electrode in a sensing region of the piezoelectric cantilever. The piezoelectric cantilever also includes a lever region, which does not have an electrode for capturing electrical energy due to the inherent extra capacitance. In some cases, the lever region may include a conductive material that is not electrically connected and does not affect capacitance.

In some aspects, the lever region may include an embossed structure or a plurality of embossed structures on the lever region of the piezoelectric cantilever. For example, the embossed structure may be an embossed portion (or embossed region) of the lever region. In this case, the embossed structure may add rigidity to the lever region and impede the application of stress within the lever region. In this case, the mechanical energy applied to the piezoelectric cantilever transfers into the sensing region, which includes an electrode. The stress transferred into the electrode in the sensing region generates a higher voltage based on the additional stress. In some aspects, the piezoelectric cantilever produces a higher voltage due to reducing the size of the electrode and its corresponding capacitance and maximizing the stress applied to the electrode.

Additional details associated with such device structures and improved device performance are provided below with respect to the figures.

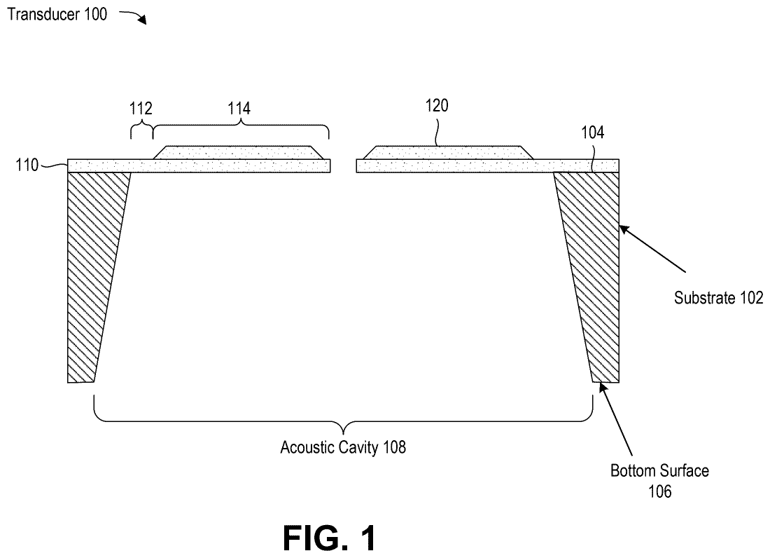

FIG. 1 illustrates a MEMS transducer 100 including an embossed structure in accordance with aspects described herein. The MEMS transducer 100 includes a substrate 102 (e.g., a semiconductor substrate such as silicon (Si)) having a top surface 104 and a bottom surface 106. An acoustic cavity 108 is formed through the substrate 102, with the acoustic cavity 108 bounded by an aperture in the top surface 104 and an aperture in the bottom surface 106. An electroacoustic structure 110 is formed at or above the top surface 104 and an aperture of the top surface 104. The electroacoustic structure 110 includes an acoustic layer to receive acoustic vibrations passing through the acoustic cavity 108 and transduce the vibrations (e.g., sound) into an electrical signal via the electroacoustic structure 110.

In one aspect, the electroacoustic structure 110 includes a piezoelectric structure configured to convert mechanical energy into electrical energy. For example, the acoustic cavity 108 receives physical energy (e.g., acoustic signals) through the electroacoustic structure 110 and displaces (e.g., vibrates) based on the physical energy. The electroacoustic structure 110 may be a piezoelectric cantilever that includes a sensing region 112 and a lever region 114. The vibrations applied to the acoustic cavity 108 may be converted into electrical energy based on the piezoelectric effect that is applied to the lever region 114 and the sensing region 112. The piezoelectric effect is the ability of certain materials (e.g., quartz) to generate an electric charge in response to an applied mechanical stress. For example, a voltage can be generated based on providing an acoustic signal into the electroacoustic structure 110. In one aspect, the lever region 114 can include an embossed structure 120 that impedes stress and transfers the stress into the sensing region 112 to increase signal strength generated by the electroacoustic structure 110.

In some aspects, the energy produced by the electroacoustic structure 110 is based on the mechanical stress captured at an electrode. When a piezoelectric material (e.g., the electroacoustic structure 110) is compressed, the piezoelectric material generates a charge proportional to the applied force based on an electrode disposed within the area occupied by the electrode. The generated electrical charge and the capacitance of the electrode, which is based on the geometry of the electrode and dielectric properties, determine the generated voltage.

For example, in the electroacoustic structure 110, as capacitance increases, the voltage decreases. Maximizing voltage is important because the signals are amplified, and lower voltage can introduce various noises (e.g., thermal noise) that affect the performance of the MEMS transducer 100. For example, higher voltage directly translates into higher SNR performance by minimizing the effects of noise.

In some aspects, the electroacoustic structure 110 includes a plurality of piezoelectric cantilevers that are configured to cover the acoustic cavity 108. The piezoelectric cantilevers respond to acoustic pressure and each generates an electrical signal.

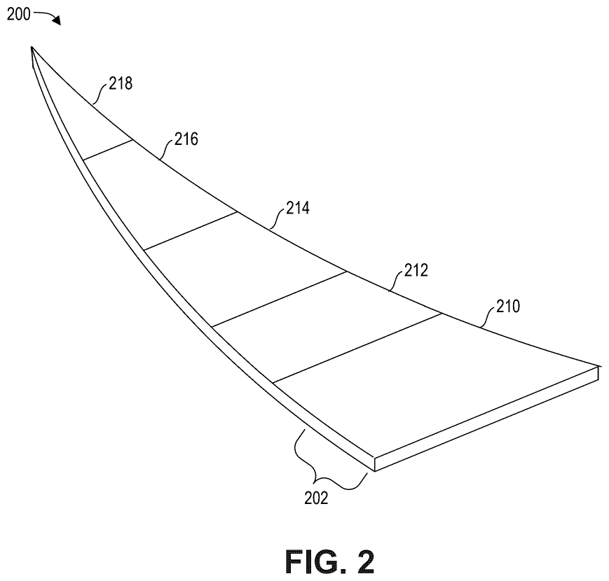

FIG. 2 is a perspective view of a piezoelectric cantilever and stress applied at different portions of the piezoelectric cantilever. The piezoelectric cantilever 200 is being displaced due to an acoustic signal (e.g., mechanical energy) and different stress is applied to the piezoelectric cantilever 200 based on distance from an anchor region 202. The anchor region 202 is mechanically attached to the top surface of a transducer (e.g., the top surface 104 in FIG. 1), and stress applied to the piezoelectric cantilever 200 increases based on distance from the tip to the anchor region 202.

For example, the most stress is applied a portion region 210 that is closest to the anchor region 202 and the least stress is applied to the anchor region. The second most amount of stress is applied to a second region 212, an average amount of stress is applied to a middle region 214, a lower amount of stress is applied to a near tip region 216 region, and the even lower stress is applied a tip region 218.

In this case, an electrode (not shown) is positioned between within the second region 212. The mechanical stress at this location produces a voltage based on the stress within the second region 212.

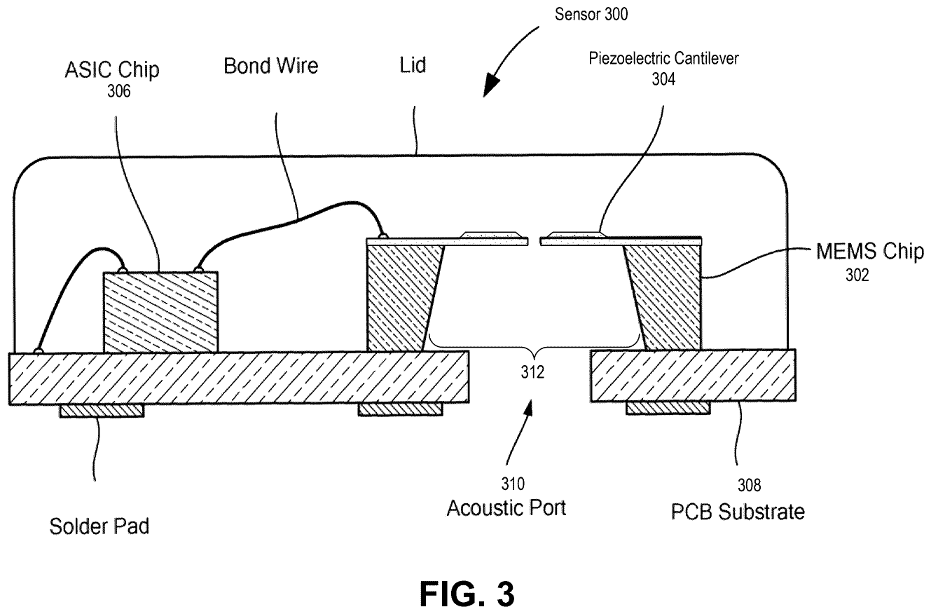

FIG. 3 illustrates aspects of a MEMS sensor 300 in accordance with aspects described herein. The MEMS sensor 300 includes a MEMS chip 302 having a transducer. The transducer may include a plurality of piezoelectric cantilevers 304 for generating electrical signals based on an acoustic signal applied to the MEMS sensor. The piezoelectric cantilevers 304 may include embossed structures to add rigidity, which in turn increases the output signal strength from the transducer. In some aspects, an embossed region increases rigidity by introducing geometric stiffening to enhance the material resistance to deformation under load. The raised profile alters the moment of inertia to redistribute stress and reduce flexural strain across the surface.

Additionally, the MEMs sensor 300 includes a lid, an application specific integrated circuit (ASIC) chip 306, and a printed circuit board (PCB) substrate 308. As shown by FIG. 3, transducers (e.g., the MEMS transducer 100 of FIG. 1) can be implemented on a MEMS chip 302 formed using a substrate (e.g., substrate 102 in FIG. 1). In some aspects, the MEMS chip 302 can include multiple transducers or other devices (not shown) in addition to the acoustic MEMS transducer. The sensor 300 includes an acoustic port 310 formed in the PCB substrate 308, and the PCB substrate 308 supports the MEMS chip 302 and the ASIC chip 306. The acoustic port 310 leads to a bottom aperture of the acoustic cavity 312 in the substrate 102 of the MEMS chip 302. In other implementations, other such configurations of the acoustic port 310 can be used so long as a path for acoustic pressure to reach the electroacoustic structures (e.g., the piezoelectric cantilevers) is present.

The ASIC chip 306 and the MEMS chip 302 may connected by an interconnect such as bond wires. In some aspects, rather than implement the system with two separate chips, some variants may implement both the MEMS chip 302 and the ASIC chip 306 as part of the same die. Accordingly, illustration of separate chips is for illustrative purposes only. In addition, in other embodiments the ASIC chip 306 may be implemented on a die in a separate package with one or more interconnects electrically coupling the MEMS chip 302 to the ASIC chip 306.

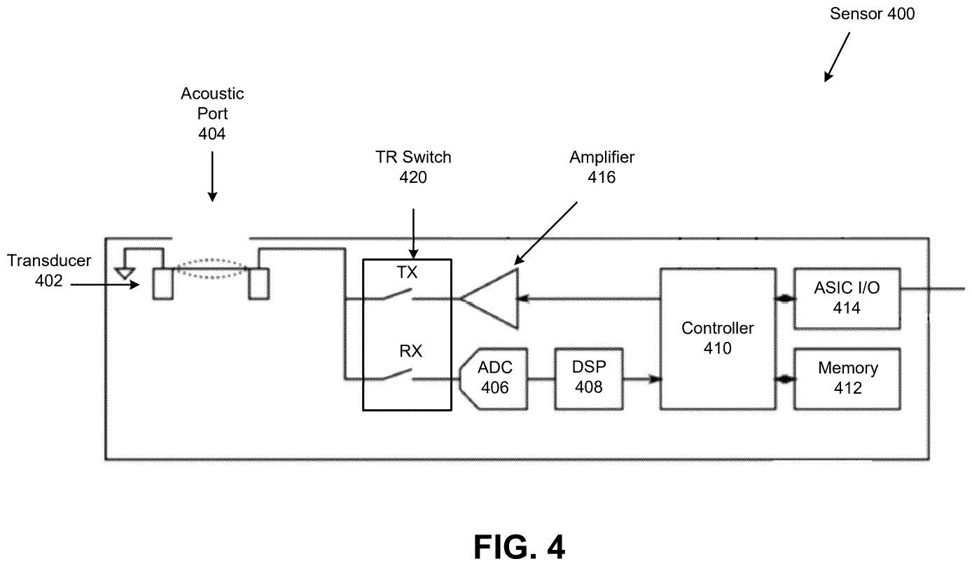

FIG. 4 illustrates aspects of a piezoelectric MEMS sensor 400 in accordance with aspects described herein. The sensor 400 includes a piezoelectric MEMS transducer 402 that interfaces with an acoustic port 404 for receiving acoustic signals. For example, the piezoelectric MEMS transducer 402 can be implemented on a MEMS chip (e.g., the MEMS chip 302 of FIG. 3). An output of the piezoelectric MEMS transducer 402 is coupled to an analog-to-digital converter (ADC) 406, which accepts an analog signal from the output of the transducer and converts the analog signal (e.g., which is a transduced signal from motion vibrations detected at the transducer 1) to a digital signal. An output of the ADC 406 is provided to a digital signal processor (DSP) 408, which can perform preprocessing, digital filtering, or other signal conditioning on the information from the transducer and provide an output signal to a controller 410. The controller 410 can further process the information from the transducer to generate a digital data signal corresponding to the analog signal output from the transducer 1. The digital data signal can be stored in a memory 412 on the sensor 400 or can be output to a data path via ASIC input/output (I/O) circuitry 414.

The acoustic port 404 is aligned with an acoustic port of the piezoelectric MEMS transducer 402 (e.g., the acoustic cavity 108 in FIG. 1). The piezoelectric MEMS sensor 400 allows acoustic signals to be received by the piezoelectric MEMS transducer 402 in a receive mode and generate electrical signals. In some cases, the sensor 400 can allow acoustic waves to be transmitted from the piezoelectric MEMS transducer 402 in an acoustic signal output mode. In this case, the piezoelectric MEMS sensor 400 may include switching circuit 420, and the controller 410 may control the piezoelectric MEMS sensor 400 to select between receive (e.g., acoustic signal input) and transmit (e.g., acoustic signal output) modes.

For example, in a transmit mode, an electrical signal (e.g., a PWM signal, a digital signal, etc.) is received by the ASIC input/output (I/O) 414 and provided to the controller 410. The electrical signal is modified by the controller 410 (e.g., filtering, and shaping for the transducer) and provided to an amplifier 416.

In a receive mode, the piezoelectric MEMS transducer 402 receives incident acoustic waves via the acoustic port 404 and converts the acoustic signals into electrical signals (e.g., a continuous wave voltage). The ADC 406 and the DSP 408 convert the analog electrical signal from the piezoelectric MEMS transducer 402 to a format acceptable to the controller 410, which can either store the signal in memory 412 or transmit the signal to additional processing circuitry of a larger device via the ASIC I/O 414. For example, the MEMS transducer 402 can be integrated into a wireless earbud, which may provide the acoustic signal to a wireless device (e.g., a phone, a laptop, etc.).

In some aspects, in a transmission mode, an electrical signal is provided from the ASIC I/O 414 to the controller 410. The electrical signal may be filtered by the controller 410 to shape the signal based on the piezoelectric MEMS transducer 402. The electrical signal may be converted into an analog electrical signal at the controller 410 and provided to the amplifier 416 to boost the power of the analog electrical signal. The amplifier 416, as part of transmission operations, can perform additional waveform conditioning and amplification (e.g., via a power amplifier). The piezoelectric MEMS transducer 402 receives the analog signal and generates an acoustic signal. In some cases, the amplifier 416 may be omitted, such as when the analog signal has sufficient power for acoustic transmission.

In some aspects, multiple separate sensor packages having MEMS acoustic transducers with overstress protection can be included in a single device. In other aspects, a shared package can be used for multiple transducers (e.g., on a shared PCB substrate such as the PCB substrate 308 with the same lid).

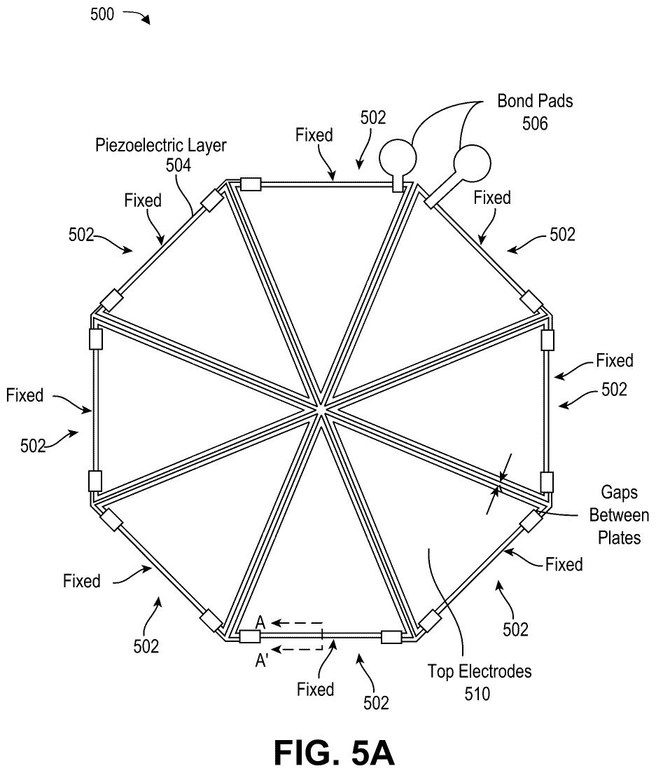

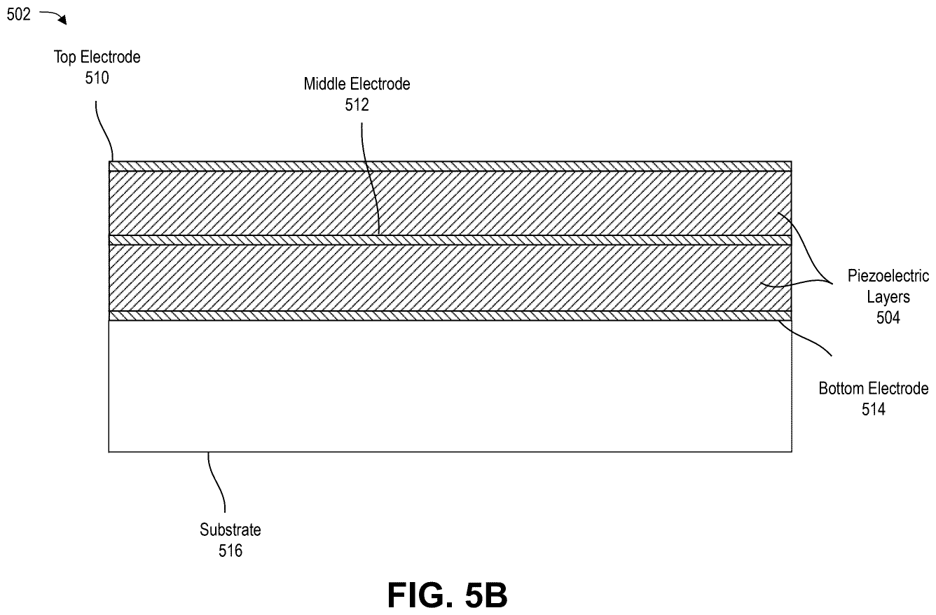

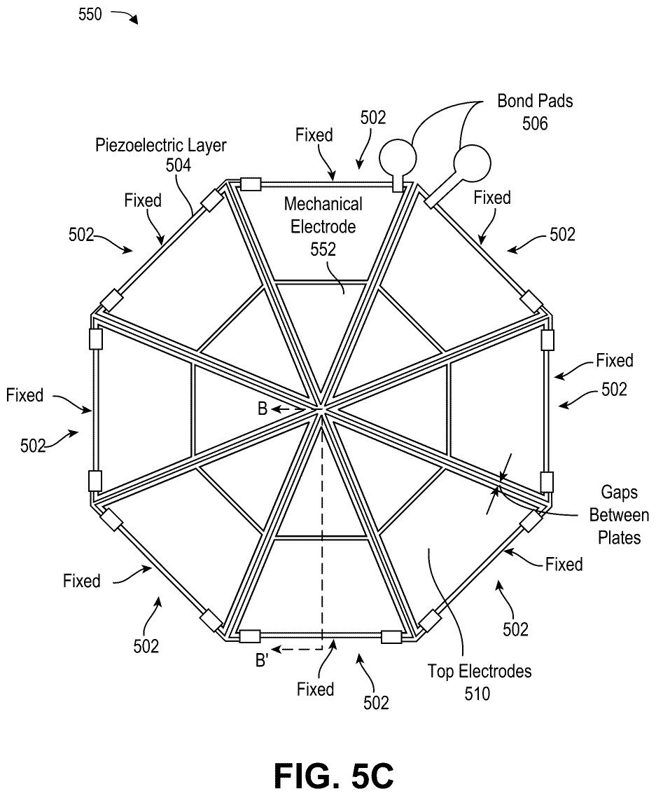

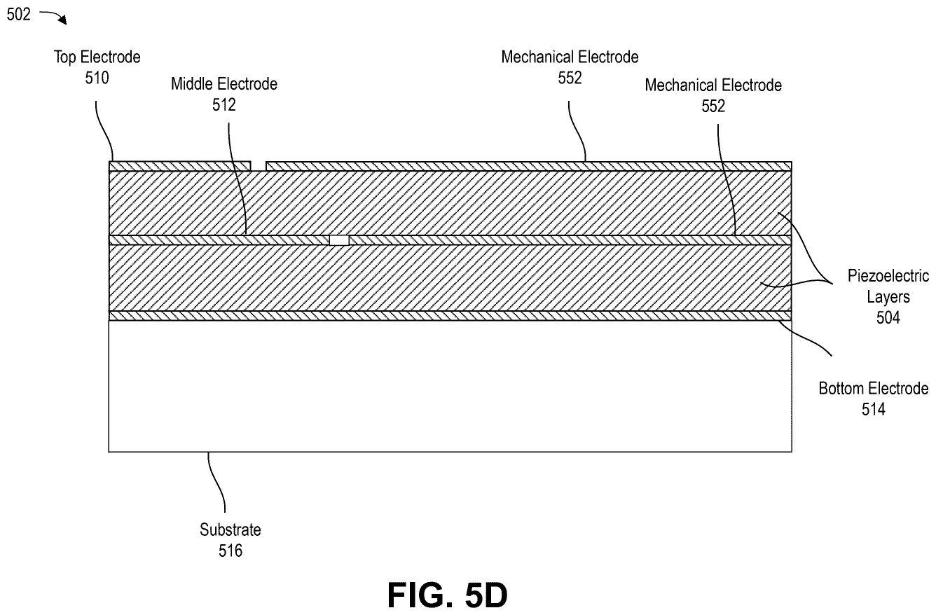

FIG. 5A illustrates a plan view of a MEMs piezoelectric transducer 500 in accordance with some aspects of the disclosure. The MEMs piezoelectric transducer 500 includes a plurality of piezoelectric cantilevers 502 that are configured to cover a cavity (e.g., the acoustic cavity 108 in FIG. 1). The piezoelectric cantilever 502 includes an associated length that is determined by the line segment from the tip of the central end that is perpendicular to the fixed end. The line segment extends from the fixed end at the substrate to the tip of the central end. As described above, when sound vibrations impact a surface of the deflection beams, the cantilevered beams will move due to the pressure (e.g., z direction movement in and out of the x-y plane illustrated in FIG. 5A). The movement in and out of this plane is referred to herein as vertical deflection. The deflection at the fixed end will be less than the deflection at the central end, with the amount of deflection increasing along the distance of the line segment away from the substrate toward the tip of the central end. The electrodes that generate the electrical signals at the bond pads 506 in response to the acoustic vibrations on the piezoelectric cantilevers 502 can add rigidity to the piezoelectric cantilever 502, and so in some implementations, placement of the top electrodes 510 can be limited to a space approximately two-thirds of the line segment distance from the fixed attachment to the substrate at the fixed end towards the tip of the central end (e.g., limited to a fixed end). In some implementations, an electrode layer can cover a surface or x-y plane cross-section of the entire illustrated fixed end of each of the cantilevered beams. In other implementations, smaller electrode shapes can be used in a portion of the fixed end of each of the piezoelectric cantilevers 502. In some aspects, the central end of each of the cantilevered beams does not include electrode layers. In some aspects, the electrode layers do not extend to the tip of the central end (e.g., the free movement end) of each piezoelectric cantilever 502 to avoid sensing movement in the deflection end (e.g., where the signal which is proportional to the stress in the cantilever is small).

Other aspects of a piezoelectric MEMS acoustic transducer may use more or fewer piezoelectric cantilevers 502. Accordingly, as with other features, the discussion of eight piezoelectric cantilevers 502 is for illustrative purposes only. The piezoelectric cantilevers 502 are fixed at their respective bases and are configured to freely move around their fixed ends as part of acoustic layer operation in response to incoming/incident sound pressure (e.g., an acoustic wave). In some cases, piezoelectric cantilevers 502 configured as triangles provide a benefit over rectangular cantilevers and can be more simply configured to form a gap controlling geometry separating an acoustic port on one side of the cantilevers of the piezoelectric MEMS acoustic transducer from an air pocket on the other side of the cantilevers. In one example, when the piezoelectric cantilevers 502 bend up or down due to either sound pressure or residual stress, the gaps between adjacent piezoelectric cantilevers 502 remain relatively small and uniform in the example symmetrical shapes with fixed ends using the piezoelectric cantilevers 502.

In some aspects, the top electrodes 510 are electrically connected in series to achieve the desired capacitance and sensitivity values. In addition to the top electrodes 510, the rest of the piezoelectric cantilever 502 also may be covered by metal to maintain certain mechanical strength of the structure. For example, in some implementations, the mechanical electrodes 512 may be covered in metal. In some cases, the mechanical electrodes 512 may not contribute to the electrical signal of the microphone output. In some aspects, a MEMS acoustic transducer can include piezoelectric cantilevers 502 without mechanical electrodes 512.

As described above, as a piezoelectric cantilever 502 bends or flexes around the fixed end as part of acoustic layer operation, the top electrodes 510 and/or the middle electrodes 512 generate an electrical signal. The electrical signal from an upward flex (e.g., as illustrated in FIG. 2) will be inverted compared with the signal of a downward flex. In some aspects, the signals from each piezoelectric cantilever 502 can be connected to the same signal path to combine the electrical signals from each piezoelectric cantilever 502 (e.g., shared bond pads 506). In other aspects, each piezoelectric cantilever 502 may have a separate signal path, allowing the signal from each piezoelectric cantilever 502 to be processed separately. In some aspects, groups of piezoelectric cantilevers 502 can be connected in different combinations. In some aspects, switching circuitry or groups of switches can be used to reconfigure the connections between multiple piezoelectric cantilevers 502 to provide different characteristics for different operating modes, such as transmit and receive modes.

In one aspect, piezoelectric cantilevers 502 can be configured in groups and share an electrical path. In one example, the piezoelectric cantilevers 502 can be divided into equal groups (e.g., a group of four) to generate a differential signal. In other aspects, the adjacent piezoelectric cantilevers 502 can be alternately connected to separate electrical paths such that every other piezoelectric cantilever 502 share a path. The electrical connections in such a configuration can be flipped to create a differential signal. Such an aspect can operate such that when an acoustic signal incident on a piezoelectric MEMS acoustic transducer causes all the cantilevers 502 to flex upward, half of the cantilevers 502 create a positive signal, and half the cantilevers 502 create a negative signal. The two separate signals can then be connected to opposite inverting and non-inverting ends of an amplifier of an analog front end. Similarly, when the same acoustic vibration causes the cantilevers 502 to flex downward, the signals of the two groups will flip polarity, providing for a differential electrical signal from the piezoelectric MEMS acoustic transducer.

Alternatively, rather than alternating piezoelectric cantilevers 502 within a single piezoelectric MEMS transducer to create a differential signal, identical MEMS transducers can be placed across a shared acoustic port with the connections to the amplifier of an analog front-end reversed and coupled to different inverting and non-inverting inputs of a differential amplifier of the analog front-end to create the differential signal using multiple piezoelectric MEMS transducers.

FIG. 5B illustrates a cross-sectional view of a MEMs piezoelectric transducer in accordance with some aspects of the disclosure. In particular, FIG. 5B shows an example cross-sectional view of one of the cantilevers 502 along lines A-A′ along the substrate.

The piezoelectric cantilever 502 can be fabricated by one or multiple layers of piezoelectric material interleaved between top electrodes 510, middle electrodes 512, and bottom electrodes 514. The piezoelectric layers 504 can be made using piezoelectric materials used in MEMS devices, such as one or more of aluminum nitride (A1N), aluminum scandium nitride (AlScN), zinc oxide (ZnO), or lead zirconate titanate (PZT). In some examples, the top electrodes 510 and/or middle electrodes 512 can be made using metal materials used in MEMS devices, such as one or more of molybdenum (Mo), platinum (Pt), nickel (Ni), and aluminum (Al), and/or any combination thereof. In some cases, the top electrodes 510, middle electrodes 512, and bottom electrodes 514 can be formed from a non-metal, such as doped polysilicon. In some implementations, the top electrodes 510 may cover only a portion of the piezoelectric cantilever 502, (e.g., from the fixed end to about one third of the piezoelectric cantilever 502), in such cases where these areas generate electrical energy more efficiently within the piezoelectric layer 504 than the areas near the central end (e.g., the free movement end) of each piezoelectric cantilever 502. For example, high-stress concentration in areas near the fixed end induced by the incoming sound pressure is converted into an electrical signal by direct piezoelectric effect.

In some aspects, adding an embossed structure to a piezoelectric cantilever may change the performance and the size of the electrodes may change. For example, an embossed structure may shift the resonance frequency of the piezoelectric cantilever and geometry of the piezoelectric cantilever can be changed to maintain the resonance frequency. For example, the size of the sensing region may be reduced to approximately 20% of the total size or length, and the lever region may be increased to approximately 80% of the total size or length) to maintain the resonance frequency of the piezoelectric cantilever.

In some aspects, the piezoelectric cantilevers 502 and corresponding layers (e.g., the top electrodes 510, middle electrodes 512, and bottom electrodes 514, and the piezoelectric layer 504) may be formed on a substrate 516 using various semiconductor processes.

FIG. 5C illustrates a plan view of a MEMs piezoelectric transducer 550 in accordance with some aspects of the disclosure. The MEMs piezoelectric transducer 550 includes a mechanical electrode 552 that is electrically isolated from the top electrode 510. For example, a region between the top electrodes 510 and the mechanical electrode 552 can be etched during manufacturing.

FIG. 5D illustrates a cross-sectional view of a MEMs piezoelectric transducer in accordance with some aspects of the disclosure. In particular, FIG. 5D shows an example cross-sectional view of one of the cantilevers along lines B-B′. The top electrodes 510 and the mechanical electrode 552 are formed on the same piezoelectric layer 504 and are separated by a gap. In this case, the mechanical electrode 552 does not contribute any capacitance to other electrical components. The inner conductive layers may also include a corresponding gap at the same or different horizontal positions.

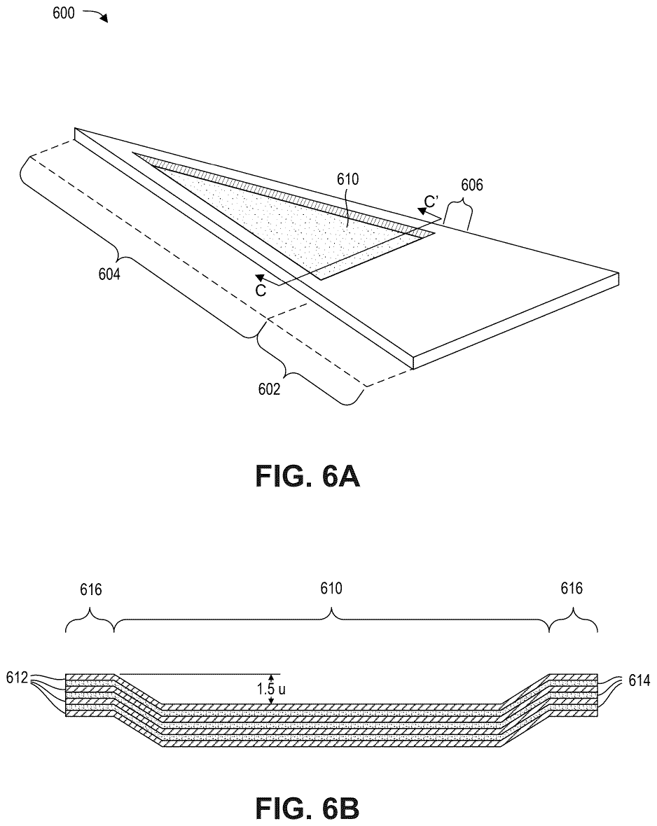

FIG. 6A illustrates a piezoelectric cantilever 600 including an embossed structure 610 in accordance with some aspects of the disclosure. In some aspects, the piezoelectric cantilever 600 is divided into a sensing region 602 (e.g., a first section) that includes an electrode (not shown) and a lever region 604, which may include a mechanical electrode (e.g., the mechanical electrode 552 in FIG. 5C) that is electrically isolated from other electrical components. The lever region 604 may further include an embossed structure 610 that is configured to increase rigidity of the piezoelectric cantilever 600. In one aspect, the lever region 604 can be a non-planar portion of the lever region 604. For example, the lever region 604 may be configured to have an embossed section having a lowered or raised height with respect to the sensing region 602.

The embossed structure 610 is configured to increase the rigidity of the lever region 604. For example, the embossed structure 610 increases rigidity by introducing geometric stiffening to enhance the material resistance to deformation under load and alters the moment of inertia to redistribute stress and reduce flexural strain across the surface. In turn, when an acoustic signal or other mechanical force is applied to the lever region 604, the lever region 604 will resist (e.g., impede) the mechanical force. For example, in a conventional piezoelectric cantilever (e.g., the piezoelectric cantilever 200 in FIG. 2), the mechanical stress is increases proportionally to the distance from the tip to the edge of the anchor (e.g., the anchor region 202 in FIG. 2).

In some aspects, the embossed structure 610 is an embossed portion of the lever region 604. The addition of ridges and valleys causes the material to be less likely to bend or deform based on reinforcement in multiple planes. In some cases, embossing of the lever region 604 to create the embossed structure 610 does not add additional material and prevents mass loading from affecting other properties of the piezoelectric cantilever 600. For example, adding additional material to the piezoelectric cantilever 600 may change the sensitivity, the resonance frequency, and the vibration mode. In some cases, the electroacoustic properties of the piezoelectric layers (e.g., the piezoelectric layer 504 in FIG. 5B) may change based on the weight applied to the piezoelectric layers. For example, in the case that additional metal is formed on the piezoelectric cantilever 600, a piezoelectric layer may have different properties that vary based on the mass load on that portion of the piezoelectric cantilever 600.

In some aspects, the embossed structure 610 can change a resonance frequency without affecting other parameters such as sensitivity (e.g., which may be based on mass) and vibration mode. For example, the embossed structure 610 may increase the resonance frequency relative to a cantilever with the same dimensions. The increased resonance frequency may increase the bandwidth of a device (e.g., of a microphone). In some cases, the cantilever can be elongated to match the desired resonance frequency and increase signal output.

The embossed structure 610 can be configured to have a variety of configurations. For example, the piezoelectric cantilever 600 comprises a shape that is vertically offset (e.g., increased or decreased) relative to the sensing region. For example, the embossed structure 610 is a raised triangle area. In some cases, the embossed structure 610 may be a circle, a square, etc. In other cases, the embossed structure 610 may include sidewalls that form a larger geometric volume, such as a pyramid or a portion of a taurus. In some cases, the larger geometric volume can increase the surface area of the piezoelectric cantilever 600, which may be beneficial in a variety of different applications. For example, a larger surface area may be preferable based on the specific dimensions of the MEMS transducer.

In some aspects, the embossed structure is configured to have a vertical offset of approximately 1.5 microns with respect to the sensing region, and a thickness of the piezoelectric materials can be approximately 0.9 microns. In some cases, the offset can be more or less and may be based on manufacturing processes (e.g., deposition limitations, process step, etc.) and lifecycle requirements. For example, an embossed structure having a higher process step may cause the piezoelectric materials to reduce height perpendicular to the non-planar portion of the embossed structure, which can reduce the strength of the materials (e.g., causing the piezoelectric materials to become more brittle and susceptible to failure). In some cases, the piezoelectric cantilever 720 can be realized as a fully three-dimensional shape such as a pyramid, a partial torus, a cylinder, and so forth. The height of the embossed structure 610 may also affect rigidity and corresponding resonance frequency. In such a case, the embossed structure 610 may include a higher vertical offset (e.g., 5 microns) to increase the rigidity.

In this case, the embossing creates raised patterns that increase the overall surface area and distribute applied forces more evenly, reducing stress in the lever region 604 without changing the mass of the piezoelectric cantilever 600. In some aspects, the sum of all energies must be zero, and the stress is channeled from the lever region 604 into the sensing region 602. In this case, the stress within the region 606 increases and can generate a signal with higher voltage (e.g., higher power). The higher voltage provides better acoustical performance, such as increased SNR and higher dynamic range.

Based on the stress within the boundary region 606, the stress applied to the sensing region 602 increases, increasing the voltage generated by the electrode in the sensing region 602. In some aspects, the electrical energy captured by the electrode in the sensing region 602 increases.

In some aspects, the output voltage of a MEMS microphone represents the intensity of the incoming sound waves, and higher voltages correspond to higher sensitivity and enable better detection of the sound details. Improved detection of sound improves separation of the actual audio signal from background noise and increases dynamic range (e.g., capturing both soft and loud sounds accurately without distortion). Higher sensitivity also increases SNR, which is perceived as the clarity of the audio signal relative to background noise. Higher sensitivity output enables subsequent processes to better distinguish between subtle sounds and ambient noise, resulting in a cleaner recording. Low sensitivity increases noise as the output signal is weaker, making it more susceptible to electrical noise from the surrounding circuitry. Lower sensitivity reduces the SNR and may prevent the removal of the background noise. Lower sensitivity can also increase distortion and clipping, particularly when the recorded audio has a high dynamic range.

In some cases, the embossed structure is configured to have a vertical offset of approximately 1.5 microns with respect to the sensing region. In some cases, the offset can be more or less and may be based on manufacturing processes (e.g., deposition limitations, process step, etc.) and lifecycle requirements. For example, an embossed structure having a higher process step may cause the piezoelectric materials to have a height perpendicular to the non-planar portion of the embossed structure to decrease, which can reduce the strength of the materials (e.g., causing the piezoelectric materials to become more brittle and susceptible to failure). Higher rigidity can be beneficial, but may also be detrimental in some cases based on excessive strain at specific points, creating points of failure.

FIG. 6B is a cross-section of the piezoelectric cantilever 600 along line C-C′ in accordance with some aspects of the disclosure. In some aspects, the piezoelectric cantilever 600 is formed by a MEMS stack such as interleaving electrode layers 612 (e.g., the top electrodes 510, the middle electrodes 512, and the bottom electrodes 514 in FIG. 5B) and piezoelectric layers 614 (e/g., the piezoelectric layer 504 in FIG. 5B).

In some aspects, the embossed structure 610 is embossed (e.g., by 1.5 microns) and forms an edge region 616 on each side of the embossed structure 610. Each edge region 616 provides a path to transfer mechanical energy (e.g., from an applied acoustic signal) from the lever region 604 into the sensing region 602. In some aspects, the stress from the sensing region of the piezoelectric cantilever 600 decreases toward a tip of the piezoelectric cantilever 600.

FIG. 6C is a plan view of the piezoelectric cantilever 600 in accordance with some aspects of the disclosure. In some aspects, the embossed structure 610 consumes a significant portion of the lever region 604 and provides edge regions 616 at the lateral sides of the lever region 604. The edge region 616 extends from and edge of the embossed structure 610 to the edge of the lever region 604.

In some aspects, the embossed structure 610 causes the piezoelectric cantilever 600 to have a different resonance frequency. In this case, the dimensions of the piezoelectric cantilever 600 may be changed to maintain the same resonance frequency (e.g., before the embossed structure). In one aspect, the length of the lever region 604 can be increased, and the length of the sensing region 602 can be decreased. For example, the length of the sensing region 602 can be 20% of the total length of the piezoelectric cantilever 600 (e.g., 40 μm or 40 microns) and the length of the lever region 604 can be 80% of the total length of the piezoelectric cantilever 600 (e.g., 160 μm).

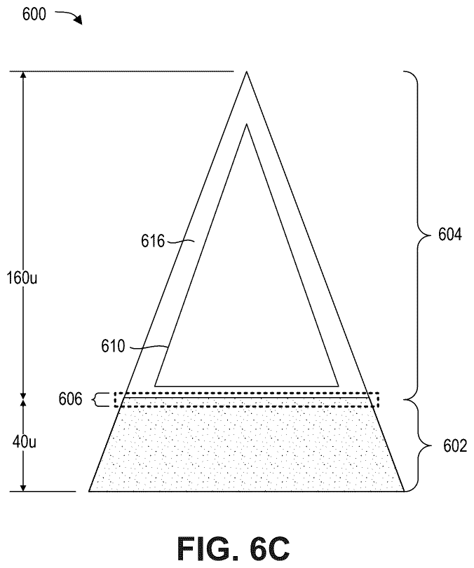

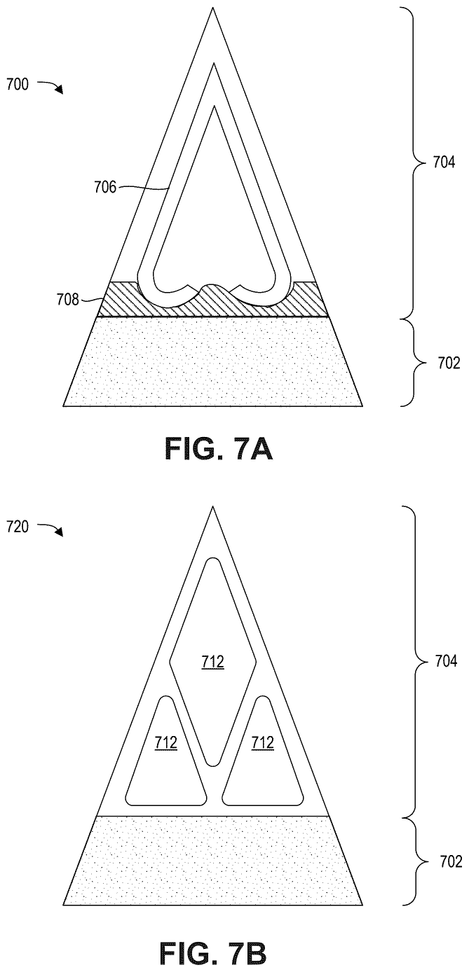

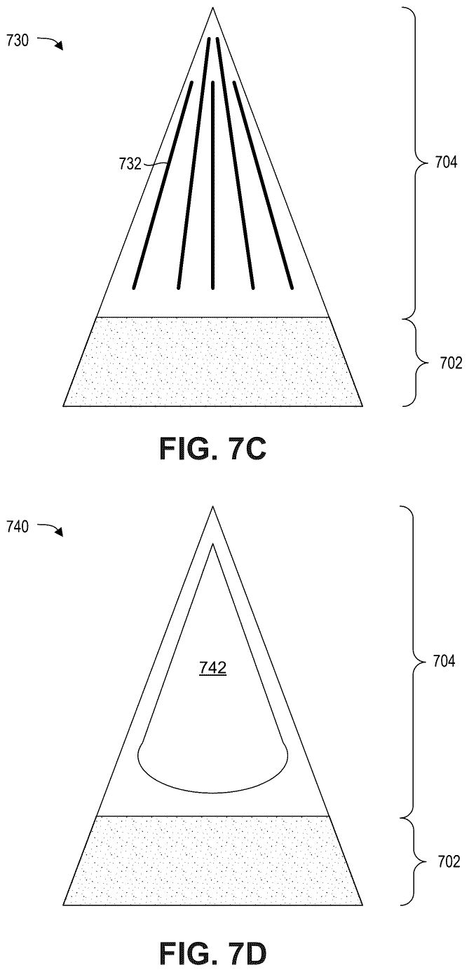

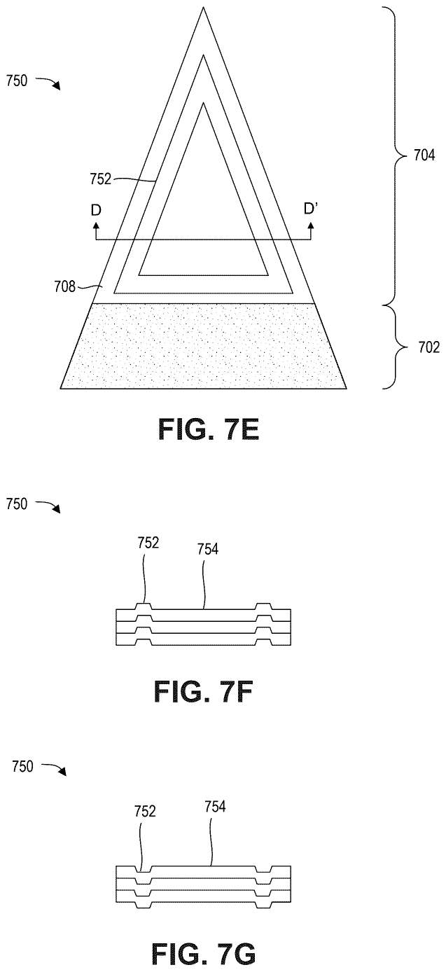

FIG. 7A illustrates a piezoelectric cantilever 700 having an embossed structure including stress dispersing features in accordance with some aspects of the disclosure. The piezoelectric cantilever 700 includes a sensing region 702 and a lever region 704. An electrode for sensing stress and converting the stress into voltage is disposed in the sensing region 702.

In some aspects, an embossed structure 706 can have a complex base shape that borders the sensing region. For example, the embossed structure 706 may correspond to an inverted heart shape. In this case, the inverted heart shape 706 corresponds to the embossed region (e.g., a region in which the top surface on either side of the region 706 is raised or higher than a top surface of the region 706 such that there are sidewalls of some slope around the perimeter of the region 706). In this configuration, the embossed structure 706 spreads stress around the edges of the inverted heart shape and smooths the application of stress at hard edges. In another example, the embossed structure 706 can correspond to a cone with a semicircle base. In this aspect, smooth transitions (e.g., the non-linear curves) spread the stress from specific points across the horizontal plane in the piezoelectric cantilever 700. For example, the boundary region 708 may include non-linear portions that evenly distribute the stress across the horizontal plane of the piezoelectric cantilever 700. For example, sharp geometry transitions (e.g., a corner) create a bottleneck for the stress lines and concentrate stress in a smaller area. The increased stress concentration significantly increases the local stress at geometry transitions as compared to the average stress. Rounded and smoothed geometry transitions provide a gradual transition and allow stress lines to flow more smoothly to reduce the disruption of stress flow and provide a more uniform distribution of stress. Minimizing local stress at specific points may prevent stress from weakening specific points and increase the lifespan of the piezoelectric cantilever 700.

FIG. 7B illustrates a piezoelectric cantilever 720 having an embossed structure including stress dispersing features in accordance with some aspects of the disclosure. The piezoelectric cantilever 720 includes a plurality of embossed structures 712 that at least partially overlap in a vertical direction. In this example, the addition of multiple embossed structures 712 can increase the rigidity of the piezoelectric cantilever 700. In addition, the embossed structures 712 may include rounded edges to spread stress laterally and minimize single points of failure.

FIG. 7C illustrates a piezoelectric cantilever 730 having an embossed structure configured in a single axis in accordance with some aspects of the disclosure. The piezoelectric cantilever 730 includes a plurality of embossed structures 732 that are trench-like structures that are generally configured in a single direction (e.g., vertical) and have a corrugated profile. The embossed structures 732 may have different lengths, to allow configuration of custom rigidity at different points of the piezoelectric cantilever 730. The embossed structures 732 are generally configured in the vertical direction and consume an insignificant amount of horizontal space. For example, the embossed structure 732 may have a corrugated profile. In some aspects, the piezoelectric cantilever 730 can be realized by embossing a linear region. For example, a cross-section of the embossed structures 732 in a horizontal place may have a semicircle, trapezoidal, or triangular profile. An example of a trapezoidal cross-section is illustrated in FIG. 7F.

FIG. 7D illustrates a piezoelectric cantilever 740 having an embossed structure including stress dispersing features in accordance with some aspects of the disclosure. The piezoelectric cantilever 740 includes an embossed structure 742 having a conical shape with a semicircle base. In this example, the embossed structure 742 may include rounded edges to spread stress laterally and minimize single points of failure.

FIG. 7E illustrates a piezoelectric cantilever 750 having an embossed border structure in accordance with some aspects of the disclosure. In this case, a border of a shape is embossed into the piezoelectric cantilever 750 and a central region of the shape remains planar with the sensing region 702. For example, a border region corresponding to a triangular shape is embossed in the piezoelectric cantilever 750.

FIG. 7F is a cross-section of the piezoelectric cantilever 750 along line D-D′ in accordance with some aspects of the disclosure. In this case, a center region 754 associated with the embossed structure 752 remains planar with respect to the sensing region 702.

FIG. 7G is another cross-section of the piezoelectric cantilever 750 along line D-D′ in accordance with some aspects of the disclosure. In this case, the embossed structure 752 is below the planar region, and a center region 754 associated with the embossed structure 752 remains planar with respect to the sensing region 702.

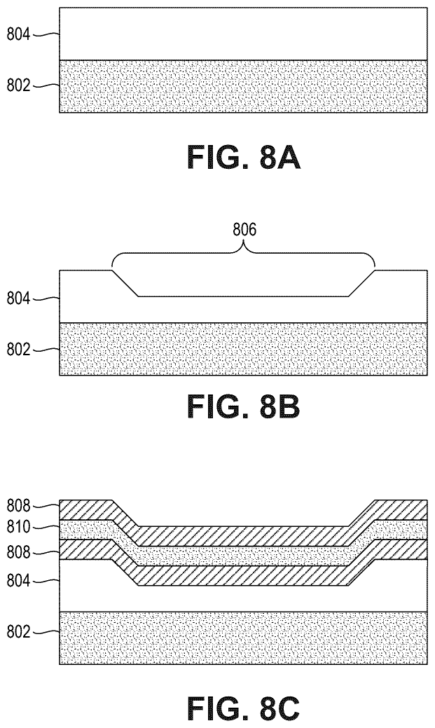

FIGS. 8A-8C illustrate a process of generating a piezoelectric cantilever for a MEMS transducer in accordance with some aspects of the disclosure. Initially, in FIG. 8A, a protective layer 804 (e.g., a mask, etc.) is formed over a substrate 802.

In FIG. 8B, a portion of the protective layer 804 is selectively removed to form a recess region 806. For example, a portion of the protective layer 804 may be etched using various processes. In some aspects, the recess region 806 may correspond to the shape of an embossed structure.

In FIG. 8C, a conductive layer 808 may be formed over the surface of the protective layer 804, at least one piezoelectric layer 810 is formed over the protective layer 804, and a conductive layer 808 is formed over the piezoelectric layer 810. FIG. 8C illustrates a single piezoelectric layer. However, multiple piezoelectric layers may be interleaved between additional layers of conductive layers to create a stack (e.g., a MEMS stack). The conductive layer 808 and the piezoelectric layer 810 can be formed via various processes such as deposition, sputtering, atomic layer deposition, and so forth.

In some aspects, the substrate 802 and the protective layer 804 may be selectively removed to form a piezoelectric cantilever including an embossed structure. In some cases, a cavity can be formed in the substrate 802 to create a path for acoustic signals to be applied to the piezoelectric cantilever. For example, a deep reactive ion etching can be performed to remove all material below the piezoelectric cantilever. A portion of the piezoelectric cantilever may be fixed to the substrate 802 that corresponds to a transducer body (e.g., the substrate 102 in FIG. 1).

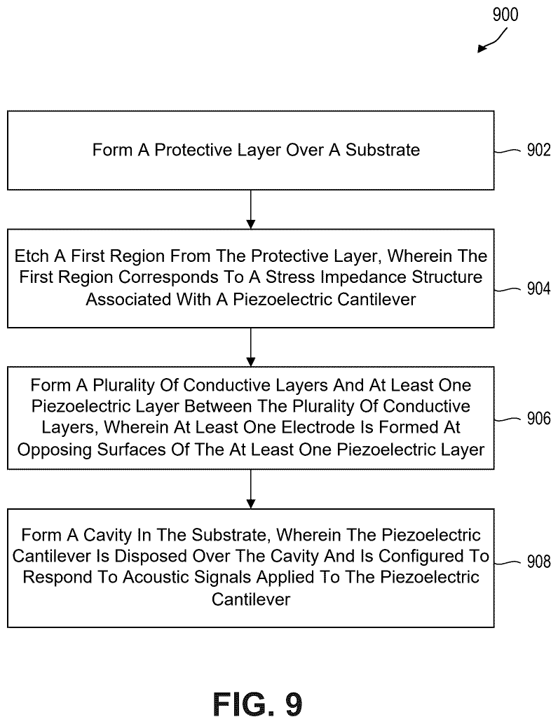

FIG. 9 illustrates a method 900 (or process) for forming a MEMS transducer including a piezoelectric cantilever with an embossed structure in accordance with some aspects of the disclosure.

At block 902, the method includes forming a protective layer over a substrate. For example, the substrate may be a silicon substrate, which may already have additional other components formed thereon.

At block 904, the method includes etching a first region from the protective layer. The first region corresponds to an embossed structure associated with a piezoelectric cantilever (e.g., the piezoelectric cantilever 700 in FIG. 7A).

At block 906, the method includes forming a plurality of conductive layers and at least one piezoelectric layer between the plurality of conductive layers. At least one electrode is formed at opposing surfaces of the at least one piezoelectric layer. For example, the plurality of conductive layers and at least one piezoelectric layer may be referred to as a MEMS stack and can be used to form a piezoelectric device, such as a piezoelectric cantilever.

At block 908, the method includes forming a cavity in the substrate. After forming the cavity, the piezoelectric cantilever including the piezoelectric cantilever may be disposed over the cavity and is configured to respond to acoustic signals applied to the piezoelectric cantilever. The embossed structure increases the rigidity of the piezoelectric cantilever to transfer applied stress to the at least one electrode.

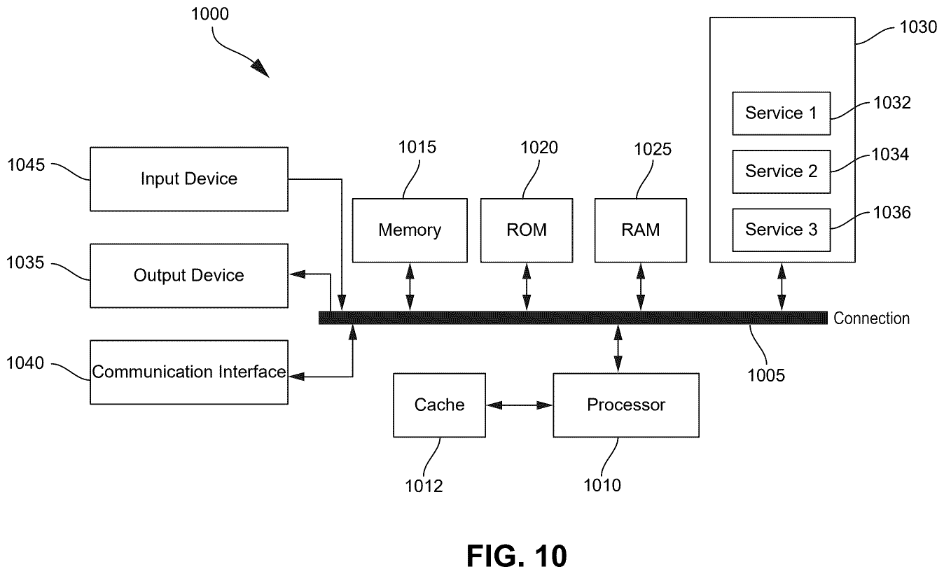

FIG. 10 is a diagram illustrating an example of a system for implementing certain aspects of the present technology. In particular, FIG. 10 illustrates an example of computing system 1000 which can include MEMS transducers or devices including MEMS devices having piezoelectric cantilevers with an embossed structure in accordance with aspects described herein. An acoustic transducer can be integrated, for example, with any computing device making up internal computing system, a remote computing system, a camera, or any component thereof in which the components of the system are in communication with each other using connection 1005. Connection 1005 may be a physical connection using a bus, or a direct connection into processor 1010, such as in a chipset architecture. Connection 1005 may also be a virtual connection, networked connection, or logical connection.

Example computing system 1000 includes at least one processing unit (CPU or processor) 1010 and connection 1005 that communicatively couples various system components including system memory 1015, such as read-only memory (ROM) 1020 and random access memory (RAM) 1025 to processor 1010. Computing system 1000 may include a cache 1012 of high-speed memory connected directly with, in close proximity to, or integrated as part of processor 1010.

Processor 1010 may include any general purpose processor and a hardware service or software service, such as services 1032, 1034, and 1036 stored in storage device 1030, configured to control processor 1010 as well as a special-purpose processor where software instructions are incorporated into the actual processor design. Processor 1010 may essentially be a completely self-contained computing system, containing multiple cores or processors, a bus, memory controller, cache, etc. A multi-core processor may be symmetric or asymmetric.

To enable user interaction, computing system 1000 includes an input device 1045, which may represent any number of input mechanisms, such as a microphone for speech or audio detection (e.g., PZ MEMS transducer or a MEMS transducer system in accordance with aspects described above, etc.) along with other input devices 1045 such as a touch-sensitive screen for gesture or graphical input, keyboard, mouse, motion input, speech, etc. Computing system 1000 may also include output device 1035, which may be one or more of a number of output mechanisms. In some instances, multimodal systems may enable a user to provide multiple types of input/output to communicate with computing system 1000.

Computing system 1000 may include communications interface 1040, which may generally govern and manage the user input and system output. The communication interface may perform or facilitate receipt and/or transmission wired or wireless communications using wired and/or wireless transducers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 1040 may also include one or more Global Navigation Satellite System (GNSS) receivers or transducers that are used to determine a location of the computing system 1000 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1030 may be a non-volatile and/or non-transitory and/or computer-readable memory device and may be a hard disk or other types of computer readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1(L1) cache, Level 2(L2) cache, Level 3(L3) cache, Level 4(L4) cache, Level 5(L5) cache, or other (L #) cache), resistive random-access memory (RRAM/ReRAM), phase change memory (PCM), spin transfer torque RAM (STT-RAM), another memory chip or cartridge, and/or a combination thereof.

The storage device 1030 may include software services, servers, services, etc., that when the code that defines such software is executed by the processor 1010, it causes the system to perform a function. In some embodiments, a hardware service that performs a particular function may include the software component stored in a computer-readable medium in connection with the necessary hardware components, such as processor 1010, connection 1005, output device 1035, etc., to carry out the function. The term “computer-readable medium” includes, but is not limited to, portable or non-portable storage devices, optical storage devices, and various other mediums capable of storing, containing, or carrying instructions(s) and/or data. A computer-readable medium may include a non-transitory medium in which data may be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the embodiments and examples provided herein, but those skilled in the art will recognize that the application is not limited thereto. Thus, while illustrative embodiments of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, embodiments may be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual embodiments may be described above as a process or method which is depicted as a flowchart, a flow diagram, a data flow diagram, a structure diagram, or a block diagram. Although a flowchart may describe the operations as a sequential process, many of the operations may be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination may correspond to a return of the function to the calling function or the main function.

Processes and methods according to the above-described examples may be implemented using computer-executable instructions that are stored or otherwise available from computer-readable media. Such instructions may include, for example, instructions and data which cause or otherwise configure a general purpose computer, special purpose computer, or a processing device to perform a certain function or group of functions. Portions of computer resources used may be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some embodiments the computer-readable storage devices, mediums, and memories may include a cable or wireless signal containing a bitstream and the like. However, when mentioned, non-transitory computer-readable storage media expressly exclude media such as energy, carrier signals, electromagnetic waves, and signals per se.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and may take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also may be embodied in peripherals or add-in cards. Such functionality may also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purpose computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium including program code including instructions that, when executed, performs one or more of the methods, algorithms, and/or operations described above. The computer-readable data storage medium may form part of a computer program product, which may include packaging materials. The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that may be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

Where components are described as being “configured to” perform certain operations, such configuration may be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

A number of implementations have been described. Nevertheless, it will be understood that various modifications may be made without departing from the spirit and scope of the disclosure. Other embodiments are within the scope of the claims.

Illustrative aspects of the disclosure include:

Aspect 1. A microelectromechanical system (MEMS) transducer, comprising: a transducer body including an acoustic cavity extending from a bottom surface to a top surface; and a piezoelectric cantilever disposed over the top surface and comprising a sensing region and a lever region including an embossed structure.

Aspect 2. The MEMS transducer of Aspect 1, wherein the piezoelectric cantilever is part of a plurality of piezoelectric cantilevers disposed over the top surface of the transducer body.

Aspect 3. The MEMS transducer of any of Aspects 1 to 2, wherein the embossed structure comprises a non-planar portion disposed in the lever region.

Aspect 4. The MEMS transducer of Aspect 3, wherein the non-planar portion is offset by 1.5 microns with respect to edges of the lever region.

Aspect 5. The MEMS transducer of any of Aspects 1 to 4, wherein the lever region includes at least one channel that is planar at an edge of the embossed structure.

Aspect 6. The MEMS transducer of any of Aspects 1 to 5, wherein the embossed structure comprises an embossed portion.

Aspect 7. The MEMS transducer of any of Aspects 1 to 6, wherein the embossed structure comprises a shape corresponding to an inner border of the piezoelectric cantilever, and wherein channels are disposed between edges of the embossed structure and corresponding edges of the piezoelectric cantilever.

Aspect 8. The MEMS transducer of any of Aspects 1 to 7, wherein the embossed structure comprises tapered edges and channels disposed between the tapered edges and corresponding edges of the piezoelectric cantilever.

Aspect 9. The MEMS transducer of Aspect 8, wherein a lower portion of the embossed structure is adjacent to the sensing region of the piezoelectric cantilever, and wherein the lower portion is linear.

Aspect 10. The MEMS transducer of any of Aspects 8 to 9, wherein a lower portion of the embossed structure is adjacent to the sensing region of the piezoelectric cantilever, and wherein the lower portion is non-linear along a boundary of the lever region and the sensing region.

Aspect 11. The MEMS transducer of Aspect 10, the lower portion reduces stress at a boundary region between the lever region and the sensing region.

Aspect 12. The MEMS transducer of any of Aspects 10 to 11, the lower portion distributes stress at a boundary region between the lever region and the sensing region.

Aspect 13. The MEMS transducer of any of Aspects 1 to 12, wherein the sensing region includes an electrode configured to convert mechanical stress generated in the lever region into electrical energy.

Aspect 14. The MEMS transducer of any of Aspects 1 to 13, wherein the lever region moves in response to acoustic signals, and wherein the sensing region generates a voltage when the lever region moves based on an acoustic signal.

Aspect 15. The MEMS transducer of any of Aspects 1 to 14, wherein a size of the lever region and the sensing region are configured to maximize a voltage generated based on a capacitance associated with an area of the sensing region.

Aspect 16. The MEMS transducer of any of Aspects 1 to 15, wherein the lever region comprises approximately 80% of the piezoelectric cantilever and the sensing region comprises approximately 20% of the piezoelectric cantilever.

Aspect 17. An apparatus, comprising: a microelectromechanical system (MEMS) transducer for generating an electrical signal based on acoustic signals, wherein the MEMS transducer includes: an acoustic cavity extending from a bottom surface to a top surface; and a piezoelectric cantilever disposed over the top surface and comprising a sensing region and a lever region including an embossed structure.

Aspect 18. The apparatus of Aspect 17, wherein the embossed structure comprises a non-planar portion disposed in the lever region.

Aspect 19. The apparatus of any of Aspects 17 to 18, wherein the embossed structure comprises an embossed portion.

Aspect 20. A method of fabricating a microelectromechanical system (MEMS) transducer, comprising: forming a protective layer over a substrate; etching a first region from the protective layer, wherein the first region corresponds to an embossed structure associated with a piezoelectric cantilever; forming a plurality of conductive layers and at least one piezoelectric layer between the plurality of conductive layers, wherein at least one electrode is formed at opposing surfaces of the at least one piezoelectric layer; and forming a cavity in the substrate, wherein the piezoelectric cantilever is disposed over the cavity and is configured to respond to acoustic signals applied to the piezoelectric cantilever, and wherein the embossed structure is increases rigidity of the piezoelectric cantilever to transfer applied stress to the at least one electrode.

Aspect 21. An acoustic transducer, comprising: a substrate having a top surface, a bottom surface opposite the top surface; an piezoelectric electroacoustic structure including at least one cantilever beam with a base coupled to the top surface of the substrate and extending over an acoustic cavity from the base to a tip, the cantilever beam formed from a layer stack comprising one or more alternating electrode layers and piezoelectric layers, the cantilever beam having a sensing region and a lever region, the sensing region positioned closer to the base than to the tip of the cantilever beam, wherein the lever region includes an embossed section.

Aspect 22. The acoustic transducer of Aspect 21, wherein the embossed section includes a first region that is recessed relative to a second region and a third region of the embossed section.

Aspect 23. The acoustic transducer of Aspect 22, wherein the first region that is recessed forms a perimeter enclosing a center region of the lever region corresponding to the second region.

Aspect 24. The acoustic transducer of Aspect 23, wherein the third region correspond to an edge region of the lever region along edges of the at least one cantilever beam.

Aspect 25. An apparatus, comprising: a substrate having a top surface, a bottom surface opposite the top surface; an piezoelectric electroacoustic structure including at least one cantilever beam with a base coupled to the top surface of the substrate and extending over an acoustic cavity from the base to a tip, the cantilever beam formed from a layer stack comprising one or more alternating electrode layers and piezoelectric layers, the cantilever beam having a sensing region and a lever region, the sensing region positioned closer to the base than to the tip of the cantilever beam, wherein the lever region includes a first region that is recessed relative to a second region and a third region.

Aspect 26. The apparatus of Aspect 25, wherein the first region that is recessed forms a perimeter enclosing a center region of the lever region corresponding to the second region.

Aspect 27. The apparatus of Aspect 26, wherein the third region correspond to an edge region of the lever region along edges of the cantilever beam.

Aspect 28. The apparatus of any of Aspects 25 to 27, wherein the first region that is recessed is arranged closer to an edge of the cantilever beam than to a center of the lever region, the second region including the edge region of the cantilever beam formed along at least a portion of the edge of the cantilever beam.

What is claimed is:

1. A microelectromechanical system (MEMS) transducer, comprising:
a transducer body including an acoustic cavity extending from a bottom surface to a top surface; and
a piezoelectric cantilever disposed over the top surface and comprising a sensing region and a lever region including an embossed structure.

2. The MEMS transducer of claim 1, wherein the piezoelectric cantilever is part of a plurality of piezoelectric cantilevers disposed over the top surface of the transducer body.

3. The MEMS transducer of claim 1, wherein the embossed structure comprises a non-planar portion disposed in the lever region.

4. The MEMS transducer of claim 3, wherein the non-planar portion is offset by 1.5 microns with respect to edges of the lever region.

5. The MEMS transducer of claim 1, wherein the lever region includes at least one channel that is planar at an edge of the embossed structure.

6. The MEMS transducer of claim 1, wherein the embossed structure comprises a shape corresponding to an inner border of the piezoelectric cantilever, and wherein channels are disposed between edges of the embossed structure and corresponding edges of the piezoelectric cantilever.

7. The MEMS transducer of claim 1, wherein the embossed structure comprises tapered edges and channels disposed between the tapered edges and corresponding edges of the piezoelectric cantilever.

8. The MEMS transducer of claim 7, wherein a lower portion of the embossed structure is adjacent to the sensing region of the piezoelectric cantilever, and wherein the lower portion is linear.

9. The MEMS transducer of claim 7, wherein a lower portion of the embossed structure is adjacent to the sensing region of the piezoelectric cantilever, and wherein the lower portion is non-linear along a boundary of the lever region and the sensing region.

10. The MEMS transducer of claim 9, the lower portion reduces or distributes stress at a boundary region between the lever region and the sensing region.

11. The MEMS transducer of claim 9, the lower portion distributes stress at a boundary region between the lever region and the sensing region.

12. The MEMS transducer of claim 1, wherein the sensing region includes an electrode configured to convert mechanical stress generated in the lever region into electrical energy.

13. The MEMS transducer of claim 1, wherein the lever region moves in response to acoustic signals, and wherein the sensing region generates a voltage when the lever region moves based on an acoustic signal.

14. The MEMS transducer of claim 1, wherein a size of the lever region and the sensing region are configured to maximize a voltage generated based on a capacitance associated with an area of the sensing region.

15. The MEMS transducer of claim 1, wherein the lever region comprises approximately 80% of the piezoelectric cantilever and the sensing region comprises approximately 20% of the piezoelectric cantilever.

16. An acoustic transducer, comprising:
a substrate having a top surface, a bottom surface opposite the top surface; and
an piezoelectric electroacoustic structure including at least one cantilever beam with a base coupled to the top surface of the substrate and extending over an acoustic cavity from the base to a tip, the at least one cantilever beam formed from a layer stack comprising one or more alternating electrode layers and piezoelectric layers, the at least one cantilever beam having a sensing region and a lever region, the sensing region positioned closer to the base than to the tip of the at least one cantilever beam, wherein the lever region includes an embossed section.

17. The acoustic transducer of claim 16, wherein the embossed section includes a first region that is recessed relative to a second region and a third region of the embossed section.

18. The acoustic transducer of claim 17, wherein the first region that is recessed forms a perimeter enclosing a center region of the lever region corresponding to the second region.

19. The acoustic transducer of claim 18, wherein the third region correspond to an edge region of the lever region along edges of the at least one cantilever beam.

20. A method of fabricating a microelectromechanical system (MEMS) transducer, comprising:
forming a protective layer over a substrate;
etching a first region from the protective layer, wherein the first region corresponds to an embossed structure associated with a piezoelectric cantilever;
forming a plurality of conductive layers and at least one piezoelectric layer between the plurality of conductive layers, wherein at least one electrode is formed at opposing surfaces of the at least one piezoelectric layer; and
forming a cavity in the substrate, wherein the piezoelectric cantilever is disposed over the cavity and is configured to respond to acoustic signals applied to the piezoelectric cantilever, and wherein the embossed structure increases rigidity of the piezoelectric cantilever to transfer applied stress to the at least one electrode.
